(19) United States
(12) Patent Application Publication
(10) Pub. No.: US 2014/0158414 A1
(43) Pub. Date: Jun. 12, 2014

(54) RECESSED DISCRETE COMPONENT MOUNTING ON ORGANIC SUBSTRATE

(71) Applicants: CHRIS BALDWIN, CHANDLER, AZ (US); MIHIR K. ROY, CHANDLER, AZ (US)

(72) Inventors: CHRIS BALDWIN, CHANDLER, AZ (US); MIHIR K. ROY, CHANDLER, AZ (US)

(21) Appl. No.: 13/711,092

(22) Filed: Dec. 11, 2012

(51) Int. Cl. H05K 1/18; H05K 3/30

(52) U.S. Cl. CPC H05K 1/181; H05K 3/30
USPC 174/260; 29/832

(57) ABSTRACT

A method and device include an organic multiple layer substrate having patterned conductors disposed on a recessed layer of the organic multiple layer substrate. A discrete component is coupled to the recessed layer such that the component is recessed from a top layer of the organic multiple layer substrate.

### BACKGROUND

Mounting of discrete components on a substrate using surface mount methods can lead to an electronics package having undesirable package height, commonly referred to as a z-height. Using surface mount technologies, discrete components, such as capacitors, resistors, inductors, and other components are typically attached to a die side substrate surface with solder balls on the substrate that are reflowed when the component is placed on the balls. This provides a secure electrical and retentive connection of the component directly to the substrate. Many times, the z-height of a resulting package and component is higher than desired in a product in which the package will be used.

### SUMMARY

A device includes an organic multiple layer substrate having patterned conductors disposed on a recessed layer of the organic multiple layer substrate. A discrete component is coupled to the recessed layer via a surface mount process such that the component is recessed from a top layer of the organic multiple layer substrate.

A method includes patterning conductors on a selected layer of an organic multiple layer substrate, forming a releasable layer on the selected layer between the patterned conductors, forming an additional layer on the selected layer and releasable layer, forming an opening through the additional layer to form a recess in the multiple layer substrate, removing the releasable layer, and attaching a component to substrate within the recess.

A further method includes patterning conductors on a selected layer of an organic multiple layer substrate, forming a releasable layer on the selected layer between the patterned conductors, forming an additional layer on the selected layer and releasable layer, forming an opening through the additional layer to form a recess in the multiple layer substrate, removing the releasable layer, and attaching the discrete component to the selected layer such that the component is recessed in the organic multiple layer substrate.

### BRIEF DESCRIPTION OF THE DRAWINGS

FIG. 1 is a cross section schematic view of an organic substrate having multiple layers, according to an example embodiment.

FIGS. 2A, 2B, 2C, 2D, and 2E are cross section schematic views of an organic substrate during build-up and component mounting, according to an example embodiment.

FIG. 3 is a cross section schematic view of an organic substrate having components recessed at multiple levels, according to an example embodiment.

### DETAILED DESCRIPTION

The following description and the drawings sufficiently illustrate specific embodiments to enable those skilled in the art to practice them. Other embodiments may incorporate structural, logical, electrical, process, and other changes. Portions and features of some embodiments may be included in, or substituted for, those of other embodiments. Embodiments set forth in the claims encompass all available equivalents of those claims.

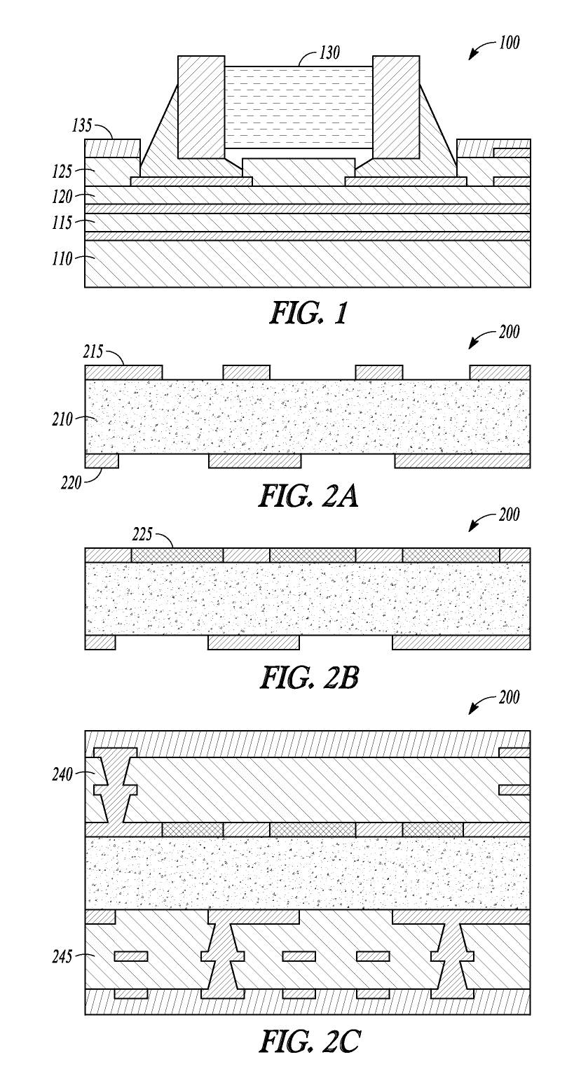

FIG. 1 is a cross section schematic view of a portion of an organic substrate 100 having multiple layers. The view may not include an entire substrate, but illustrates a specific segment or section that is relevant for the discussion. A full substrate may have many more features than depicted in FIG. 1, such as via plated through hole (PTH), die, etc. In one embodiment, the substrate 100 is formed with a bottom layer 110, second layer 115, third layer 120, and fourth layer 125, which is the last layer formed during a growing of the organic substrate 100. Bottom layer 110 may be used to mount a central processing unit or other processing element. A discrete component 130 is mounted on the third layer 120 in one embodiment, below the last layer. In further embodiments, the component may be mounted directly on even lower layers, closer to the bottom layer, or the bottom layer itself. A protective or passivation layer 135 may be added following attachment of the discrete component 130.

The discrete component 130 may be mounted on a layer by the use of a standard surface mount process corresponding to each electrical connection to be made between the component and metal lands on the corresponding layer of the substrate. In one embodiment, the surface-mount process utilizes a solder paste (solder and flux mix) that is dispensed onto lands. The discrete component 130 is placed on top of that paste and reflowed (melted) into place. In various embodiments, the discrete component may be a capacitor, resistor, inductor, or other component. Such discrete components may not be easily reduced in height. By recessing the discrete component in the substrate 100, lower Z-height profiles of resulting packages that include the substrate 100 may be obtained without expending resources in attempting to reduce the height of the components themselves. Recessing the components may also provide for reduced parasitic effects, including reduced parasitic capacitance and parasitic resistance.

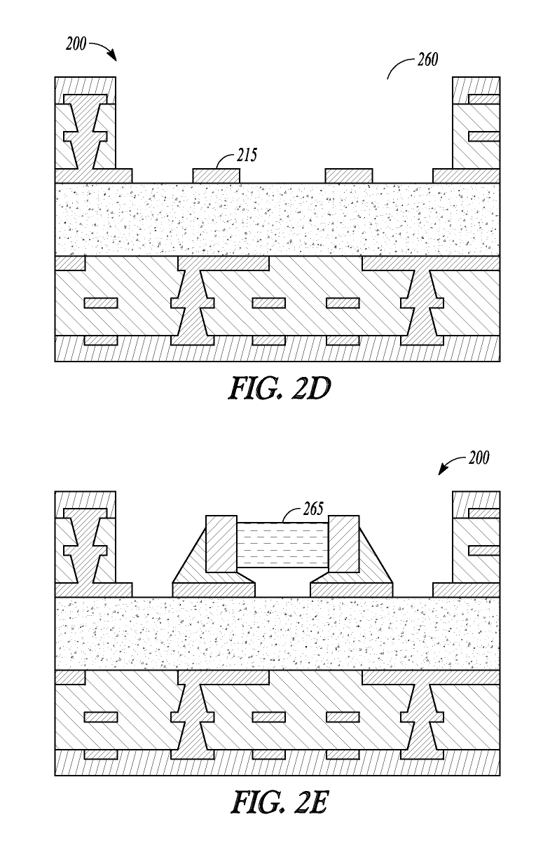

Process steps to form substrate 200 having a recessed discrete component are illustrated in schematic cross section in FIGS. 2A, 2B, 2C, 2D, and 2E. In FIG. 2A, a core layer 210 is illustrated. In one embodiment, core layer 210 forms a core of a substrate and is formed of glass reinforced resin. The entire substrate, in one embodiment, may be formed symmetrically, with multiple layers added to both sides of the core layer 210 in a semi additive process. The core layer 210, in one embodiment, is patterned on both sides with conductors 215, 220, as indicated. Conductors may also be formed between layers as illustrated. Copper is used as the conductor in one embodiment. Conductor 215 is formed on an attachment side of the substrate 200, and corresponds to connections to be made to the component when added, along with other patterning.

In FIG. 2B, a releasable film 225 has been added to the component attachment side of the substrate 200. In one embodiment, the releasable film 225 may be applied by a squeeze process, resulting in a layer that is approximately the same thickness as the conductor 215. Various releasable films may be used in different embodiments, such as common photo resists or dry films that may be stripped off at an appropriate time. The releasable film 225 is formed on top of the layer on which the component will be mounted.

FIG. 2C illustrates a build-up of additional symmetric layers 240, 245, as indicated, until a SR layer and surface finish are symmetrically applied. In one embodiment, the substrate is built up with organic materials, such as plastics and polymers, as well as metallization layers for certain conductive paths.

FIG. 2D illustrates removal of build-up layers on the component attachment side of substrate 200, where the component is to be embedded. An opening 260 is formed down to the conductor 215 level, and the releasable film 225 is also removed. The build-up layers, in one embodiment, are removed via laser scribing or other available methods. The releasable film 225 may be a resist and may be removed via common etching processes. In one embodiment, a desmear may be performed to clean out remnants from the releasable film 225. In one embodiment, the releasable film s formed on the layer on which the component is to be mounted. This layer is shown as a single layer above the core layer 210 in one embodiment, but may be any layer below an outside layer to provide for some amount of recessing of the component from a top layer of the substrate 200 when the component is mounted.

FIG. 2E illustrates a component 265 positioned in the opening 260. Prior to positioning the component 265, an organic surface protectant (OSP) surface finish for component pads may be performed, and solder paste dispensed via a nozzle or other means at selected points of attachment. Component 265 is then attached, and the solder paste reflowed to secure the component 265 to layer 240 of substrate 200.

In one embodiment, the component is recessed at or below the top surface of the substrate 200. In further embodiments, the component may be recessed such that a top of the component is still above the substrate top surface, but lower than it would be had it been attached to the substrate top surface.

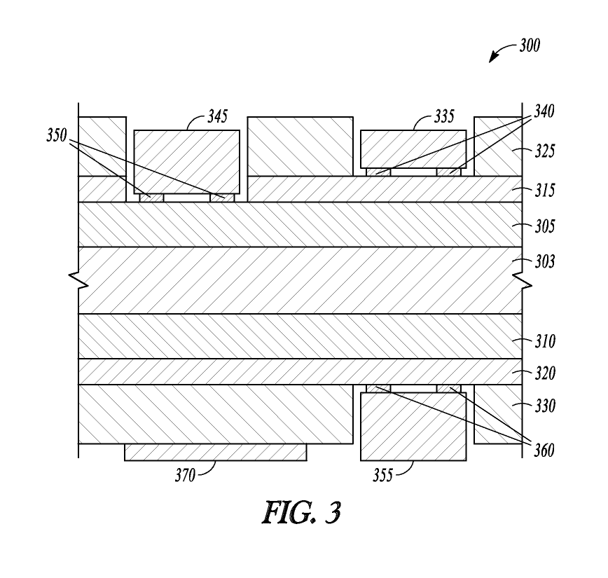

FIG. 3 is a cross section schematic view of an organic substrate 300 having components recessed at multiple levels, according to an example embodiment. Conductor patterning on and between levels is minimized in FIG. 3 to simplify the drawing. An organic core 303 has multiple symmetric organic layers 305, 310, 315, 320, 325, and 330 formed about it. Multiple discrete components are bonded to different levels on one or more sides of the core 303. On a top side of the substrate 300, a component 335 is shown mounted to layer 315 via conductors 340. A component 345 is shown mounted to layer 305 via conductors 350. Only two conductors are shown for simplicity. On a bottom side of the substrate 300, a component 355 is shown mounted to layer 320 via conductors 360. A processor 370 is also shown mounted to the bottom side of the substrate 300 on layer 330. Contacts are omitted for simplicity, but the processor may be mounted to multiple conductors via a ball grid array, surface mount process, or any type of solder connections.

### EXAMPLES

1. A method comprising:

patterning conductors on a selected layer of an organic multiple layer substrate;

forming a releasable layer on the selected layer between the patterned conductors;

forming an additional layer on the selected layer and releasable layer;

forming an opening through the additional layer to form a recess in the multiple layer substrate;

removing the releasable layer; and

attaching a component to substrate within the recess.

2. The method of example 1, wherein the substrate comprises a polymer core with multiple symmetric layers formed on a top and a bottom of the core.
3. The method of example 2, wherein forming an additional layer comprises forming multiple additional layers; and

wherein the forming an opening comprises forming a recess through multiple layers to the selected layer.

4. The method of any of examples 1-3, wherein the component is a capacitor.
5. The method of any of examples 1-4, wherein the component is a resistor.
6. The method of any of examples 1-5, wherein the component is an inductor.
7. The method of any of examples 1-6, wherein the opening is formed via laser scribing.
8. The method of any of examples 1-7, wherein the releasable layer is formed via a squeeze process.
9. The method of any of examples 1-8, wherein attaching a component to the substrate within the recess is performed by:

dispensing solder paste through a nozzle onto the patterned conductors on the selected layer;

placing the component on the solder paste; and

reflowing the solder paste to solder the component to the patterned conductors.

10. A method comprising:

patterning conductors on a selected layer of an organic multiple layer substrate;

forming a releasable layer on the selected layer between the patterned conductors;

forming an additional layer on the selected layer and releasable layer;

forming an opening through the additional layer to form a recess in the multiple layer substrate;

removing the releasable layer;

surface mounting a discrete component to the selected layer such that the component is recessed in the organic multiple layer substrate.

11. The method of example 10, wherein the substrate comprises a glass reinforced resin core with multiple symmetric layers formed on a top and a bottom of the core.
12. The method of example 11, wherein forming an additional layer comprises forming multiple additional organic layers; and

wherein the forming an opening comprises forming a recess through multiple layers to the selected layer.

13. The method of any of examples 10-12, wherein the component is a discrete capacitor.
14. The method of any of examples 10-13, wherein the component is a discrete resistor.
15. The method of any of examples 10-14, wherein the component is an discrete inductor.
16. The method of any of examples 10-15, wherein the releasable layer is formed via a squeeze process.
17. A device comprising:

an organic multiple layer substrate;

patterned conductors disposed on a recessed layer of the organic multiple layer substrate; and

a discrete component coupled to the recessed layer such that the component is recessed from a top layer of the organic multiple layer substrate.

18. The device of example 17, wherein multiple layers of the organic multiple layer substrate are symmetrically disposed about an organic core.
19. The device of any of examples 17-18, wherein the organic multiple layer substrate comprises a polymer core with multiple symmetric layers formed on a top and a bottom of the core.
20. The device of example 19, wherein the component is recessed multiple layers.
21. The device of any of examples 19-20, wherein the component is a capacitor.
22. The device of any of examples 19-21, wherein the component is a resistor.
23. The device of any of examples 19-22, wherein the component is an inductor.

Although a few embodiments have been described in detail above, other modifications are possible. For example, the logic flows depicted in the figures do not require the particular order shown, or sequential order, to achieve desirable results. Other steps may be provided, or steps may be eliminated, from the described flows, and other components may be added to, or removed from, the described systems. Other embodiments may be within the scope of the following claims, such as packages with pin grid array, land grid array, die connected to substrate through wire bond, etc.

The Abstract is provided to comply with 37 C.F.R. Section 1.72(b) requiring an abstract that will allow the reader to ascertain the nature and gist of the technical disclosure. It is submitted with the understanding that it will not be used to limit or interpret the scope or meaning of the claims. The following claims are hereby incorporated into the detailed description, with each claim standing on its own as a separate embodiment.

1. A method comprising:
patterning conductors on a selected layer of an organic multiple layer substrate;
forming a releasable layer on the selected layer between the patterned conductors;
forming an additional layer on the selected layer and releasable layer;
forming an opening through the additional layer to form a recess in the multiple layer substrate;
removing the releasable layer; and
attaching a component to substrate within the recess.

2. The method of claim 1, wherein the substrate comprises a polymer core with multiple symmetric layers formed on a top and a bottom of the core.

3. The method of claim 2, wherein forming an additional layer comprises forming multiple additional layers; and
wherein the forming an opening comprises forming a recess through multiple layers to the selected layer.

4. The method of claim 1, wherein the component is a capacitor.

5. The method of claim 1, wherein the component is a resistor.

6. The method of claim 1, wherein the component is an inductor.

7. The method of claim 1, wherein the opening is formed via laser scribing.

8. The method of claim 1, wherein the releasable layer is formed via a squeeze process.

9. The method of claim 1, wherein attaching a component to the substrate within the recess is performed by:
dispensing solder paste through a nozzle onto the patterned conductors on the selected layer;
placing the component on the solder paste; and
reflowing the solder paste to solder the component to the patterned conductors.

10. A method comprising:
patterning conductors on a selected layer of an organic multiple layer substrate;
forming a releasable layer on the selected layer between the patterned conductors;
forming an additional layer on the selected layer and releasable layer;
forming an opening through the additional layer to form a recess in the multiple layer substrate;
removing the releasable layer;
surface mounting a discrete component to the selected layer such that the component is recessed in the organic multiple layer substrate.

11. The method of claim 10, wherein the substrate comprises a glass reinforced resin core with multiple symmetric layers formed on a top and a bottom of the core.

12. The method of claim 11, wherein forming an additional layer comprises forming multiple additional organic layers; and
wherein the forming an opening comprises forming a recess through multiple layers to the selected layer.

13. The method of claim 10, wherein the component is a discrete capacitor.

14. The method of claim 10, wherein the component is a discrete resistor.

15. The method of claim 10, wherein the component is an discrete inductor.

16. The method of claim 10, wherein the releasable layer is formed via a squeeze process.

17. A device comprising:
an organic multiple layer substrate;
patterned conductors disposed on a recessed layer of the organic multiple layer substrate; and
a discrete component coupled to the recessed layer such that the component is recessed from a top layer of the organic multiple layer substrate.

18. The device of claim 17, wherein multiple layers of the organic multiple layer substrate are symmetrically disposed about an organic core.

19. The device of claim 17, wherein the organic multiple layer substrate comprises a polymer core with multiple symmetric layers formed on a top and a bottom of the core.

20. The device of claim 19, wherein the component is recessed multiple layers.

21. The device of claim 19, wherein the component is a capacitor.

22. The device of claim 19, wherein the component is a resistor.

23. The device of claim 19, wherein the component is an inductor.
